(19) United States
(12) Patent Application Publication
(10) Pub. No.: US 2025/0279388 A1
(43) Pub. Date: Sep. 4, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Fumiyoshi KAWASHIRO, Tokyo (JP)

(21) Appl. No.: 19/209,633

(22) Filed: May 15, 2025

Related U.S. Application Data
(63) Continuation of application No. PCT/JP2024/005861, filed on Feb. 19, 2024.

(30) Foreign Application Priority Data
Jul. 31, 2023 (JP) 2023-125126

(51) Int. Cl. H01L 23/00; H01L 23/31; H01L 25/07

(52) U.S. Cl. CPC H01L 24/40; H01L 23/3135; H01L 24/05; H01L 25/072; H01L 2224/05639; H01L 2224/05644; H01L 2224/05647; H01L 2224/05655; H01L 2224/05664; H01L 2224/40139; H01L 2224/40227; H01L 2224/40491; H01L 2224/4052; H01L 2225/065

(57) ABSTRACT

A semiconductor device according to the present embodiment includes a first insulating substrate having a first surface and a second surface opposite the first surface. First and second electrically conductive layers are provided on a side of the first surface. A plurality of semiconductor chips each have a third surface facing the first surface, a fourth surface opposite the third surface, a first electrode provided on the third surface, and a second electrode provided on the fourth surface. The first electrode is electrically connected to the first electrically conductive layer. A common electrode plate has a fifth surface facing the fourth surface, is electrically connected to the second electrodes of the semiconductor chips in common, and is electrically connected to the second electrically conductive layer. A second insulating substrate is provided on a side of the second surface of the first insulating substrate.

### CROSS REFERENCE TO RELATED APPLICATIONS

This application is based upon and claims the benefit of priority from the prior Japanese Patent Application No. 2023-125126, filed on Jul. 31, 2023, the entire contents of which are incorporated herein by reference.

### FIELD

The embodiments of the present invention relate to a semiconductor device.

### BACKGROUND

There is a case that a power semiconductor device used in an in-vehicle main inverter or the like is accommodated in a case. Meanwhile, as the configuration of power semiconductor devices becomes complicated, devices encapsulated with mold resin are increasing.

### BRIEF DESCRIPTION OF THE DRAWINGS

FIG. 1 is a cross-sectional view illustrating a configuration example of a semiconductor device;

FIG. 2 is a schematic plan view illustrating a configuration example of a semiconductor module;

FIG. 3 is a schematic plan view illustrating a configuration example of the semiconductor module;

FIG. 4 is a schematic cross-sectional view illustrating a configuration example of the semiconductor module;

FIG. 5 is a cross-sectional view illustrating a configuration example of a connecting part between a semiconductor chip and a common electrode plate;

FIG. 6A is a cross-sectional view illustrating an example of a manufacturing method of a semiconductor device according to a first embodiment;

FIG. 6B is a plan view illustrating an example of the manufacturing method of the semiconductor device according to the first embodiment;

FIG. 7A is a cross-sectional view illustrating an example of the manufacturing method of the semiconductor device in continuation from FIG. 6A;

FIG. 7B is a plan view illustrating an example of the manufacturing method of the semiconductor device in continuation from FIG. 6B;

FIG. 8A is a cross-sectional view illustrating an example of the manufacturing method of the semiconductor device in continuation from FIG. 7A;

FIG. 8B is a plan view illustrating an example of the manufacturing method of the semiconductor device in continuation from FIG. 7B;

FIG. 9 is a cross-sectional view illustrating an example of the manufacturing method of the semiconductor device in continuation from FIG. 8A;

FIG. 10 is a cross-sectional view illustrating an example of the manufacturing method of the semiconductor device in continuation from FIG. 9;

FIG. 11 is a cross-sectional view illustrating an example of the manufacturing method of the semiconductor device in continuation from FIG. 10;

FIG. 12 is a cross-sectional view illustrating a configuration example of a connecting part between a semiconductor chip and a common electrode plate according to a second embodiment;

FIG. 13 is a cross-sectional view illustrating a configuration example of a connecting part between a semiconductor chip and a common electrode plate according to a third embodiment;

FIG. 14 is a cross-sectional view illustrating a configuration example of a connecting part between a common electrode plate and a wire on a substrate according to a fourth embodiment;

FIG. 15 is a cross-sectional view illustrating a configuration example of a semiconductor module according to a fifth embodiment;

FIG. 16A is a cross-sectional view illustrating an example of a manufacturing method of a semiconductor device according to the fifth embodiment;

FIG. 16B is a plan view illustrating an example of the manufacturing method of the semiconductor device according to the fifth embodiment;

FIG. 17A is a cross-sectional view illustrating an example of the manufacturing method of the semiconductor device in continuation from FIG. 16A;

FIG. 17B is a plan view illustrating an example of the manufacturing method of the semiconductor device in continuation from FIG. 16B;

FIG. 18A is a cross-sectional view illustrating an example of the manufacturing method of the semiconductor device in continuation from FIG. 17A;

FIG. 18B is a plan view illustrating an example of the manufacturing method of the semiconductor device in continuation from FIG. 17B;

FIG. 19 is a cross-sectional view illustrating an example of a manufacturing method of a semiconductor device according to a sixth embodiment; and

FIG. 20 is a plan view illustrating a configuration example of a semiconductor module according to a seventh embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor device according to the present embodiment includes a first insulating substrate having a first surface and a second surface opposite the first surface. First and second electrically conductive layers are provided on a side of the first surface. A plurality of semiconductor chips each have a third surface facing the first surface, a fourth surface opposite the third surface, a first electrode provided on the third surface, and a second electrode provided on the fourth surface. The first electrode is electrically connected to the first electrically conductive layer. A common electrode plate has a fifth surface facing the fourth surface, is electrically connected to the second electrodes of the semiconductor chips in common, and is electrically connected to the second electrically conductive layer. A second insulating substrate is provided on a side of the second surface of the first insulating substrate.

### First Embodiment

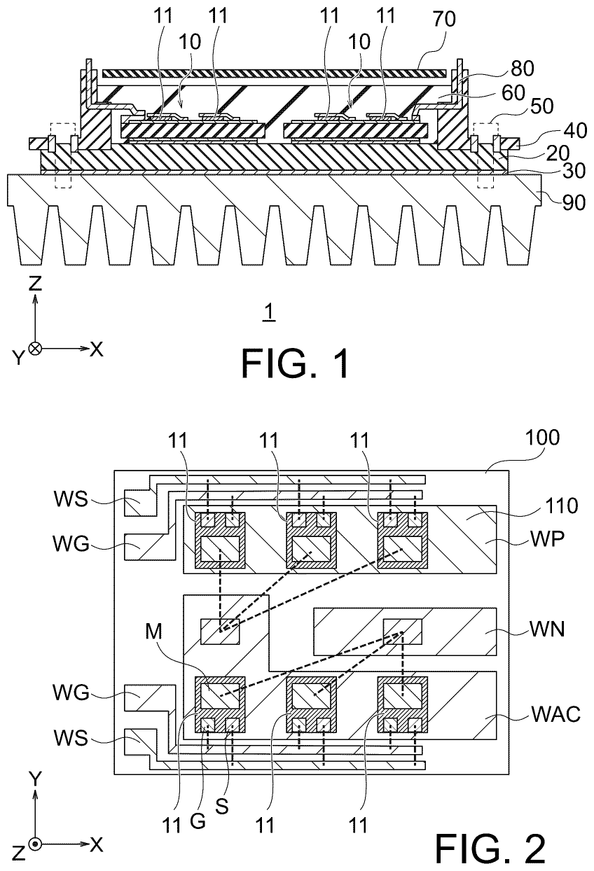

FIG. 1 is a cross-sectional view illustrating a configuration example of a semiconductor device. A semiconductor device 1 includes a semiconductor module 10, a base 20, an adhesive 30, a housing 40, a fastener 50, an encapsulation material 60, a cover 70, a wire 80, and a heat-dissipation fin 90.

The semiconductor device 1 may be a power semiconductor device that is used in an in-vehicle main inverter and switches a relatively large current with low on-resistance, for example. A stacking direction of the semiconductor module 10 with respect to the base 20 is defined as a Z-direction, one direction substantially perpendicular to the Z-direction is defined as an X-direction, and a direction substantially perpendicular to the X-direction and the Z-direction is defined as a Y-direction.

The semiconductor module 10 includes a semiconductor chip 11 and is arranged on the base 20. The semiconductor module 10 may be a power semiconductor element such as an IGBT (Insulated Gate Bipolar

Transistor), an HEMT (High Electron Mobility Transistor), a MOSFET (Metal Oxide Semiconductor Field Effect Transistor), and a diode. The semiconductor module 10 is a high-voltage power semiconductor element with a breakdown voltage of 800 V or more, for example, and may be an SiC-MOSFET module with a rated current exceeding 400 A. The detailed configuration of the semiconductor module 10 will be described later.

The base 20 has the semiconductor module 10 mounted on its front surface. The back surface of the base 20 is made to adhere to the heat-dissipation fin 90 via the adhesive 30. The base 20 is made of a material having high thermal conductivity, for example, AISiC obtained by coating an SiC substrate with aluminum. The adhesive 30 is made of an adhesive having high thermal conductivity such as solder.

The heat-dissipation fin 90 has the base 20 mounted on its front surface. The back surface of the heat-dissipation fin 90 is formed in a fin shape in order to improve the heat-dissipation property. The heat-dissipation fin 90 is made of a material having high thermal conductivity such as ceramic and metal.

The housing 40 is provided on the base 20 to surround the semiconductor module 10. The housing 40 accommodates the base 20 and the plural semiconductor modules 10 in a space surrounded by the base 20 and the housing 40. The housing 40 is made of an insulating material such as resin.

The fastener 50 penetrates through an opening formed in the housing 40 and the base 20 and is fitted to the heat-dissipation fin 90, 10 thereby fixing the housing 40 to the base 20 and further fixing the housing 40 and the base 20 to the heat-dissipation fin 90.

The encapsulation material 60 encapsulates the semiconductor modules 10 in the space surrounded by the housing 40, the base 20, and 15 the cover 70. The encapsulation material 60 may be a gel-like material that encapsulates a plurality of substrates 100 (see FIG. 4), the semiconductor chips 11, a plurality of common electrode plates 120, and the like in the above space. The encapsulation material 60 is made of an insulating material such as silicone resin and mold resin.

The cover 70 closes the opening in the housing 40 and protects the encapsulation material 60 encapsulating the semiconductor module 10. Similarly to the housing 40, the cover 70 is made of an insulating material such as resin.

The wire 80 is electrically connected to a portion of a wire of the semiconductor module 10 and passes through the encapsulation material 60 and the housing 40 to be led out to outside of the housing 40. The wire 80 is made of an electrically conductive metal such as copper.

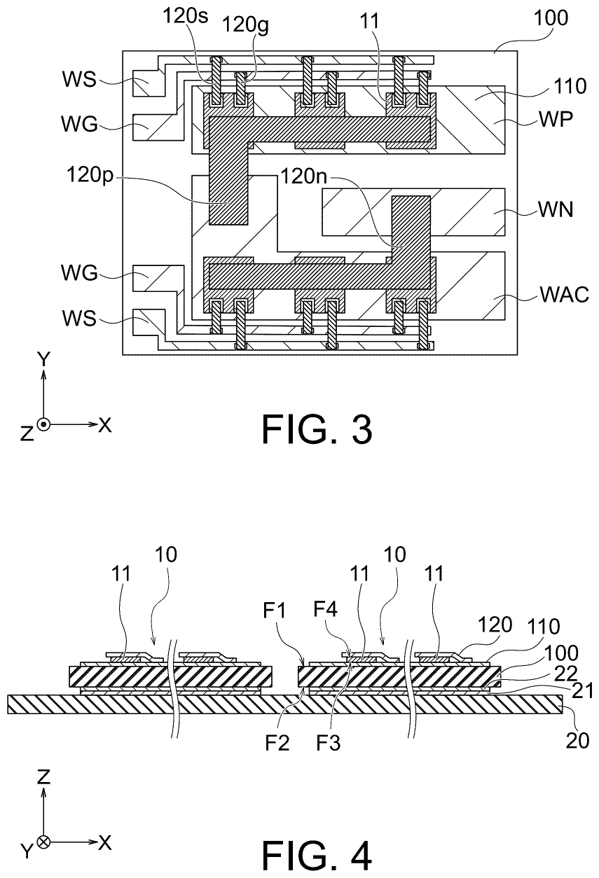

FIGS. 2 and 3 are schematic plan views illustrating a configuration example of a semiconductor module. FIG. 4 is a schematic cross-sectional view illustrating a configuration example of the semiconductor module. In FIG. 2, illustrations of common electrode plates 120g, 120s, 120p, and 120n illustrated in FIG. 3 are omitted. In FIG. 2, an electrical connection relation between each electrode of the semiconductor chip 11 and each wire on the substrate 100 is illustrated with a broken line.

As illustrated in FIG. 4, the substrate 100 as a first insulating substrate has a first surface F1 and a second surface F2 opposite the first surface F1. The substrate 100 is made of an insulating material having high thermal conductivity such as ceramic.

A wire 110 is provided on the first surface F1 of the substrate 100. The wire 110 as first and second electrically conductive layers is formed in any planar pattern on the first surface F1. The wire 110 is made of a material having high electrical conductivity and thermal conductivity, such as copper. The base 20 as a second insulating substrate is provided on the second surface F2 side of the substrate 100. A wire 22 on the substrate 100 is joined to the base 20 with a joining material 21. That is, the joining material 21 is provided between the substrate 100 and the base 20 and joins them to each other. The joining material 21 is made of an electrically conductive joining material such as solder. The wire 22 is made of the same material as the wire 110, for example, a material having high electrical conductivity and thermal conductivity such as copper. However, the joining material 21 and the wire 22 are used for thermal conduction and it is also permissible that the joining material 21 and the wire 22 are not used for electrical connection. By providing the joining material 21 and the wire 22 on the second surface F2 side, a linear expansion coefficient is balanced between the first surface F1 side and the second surface F2 side of the substrate 100, so that warpage of the substrate 100 can be prevented.

As illustrated in FIG. 2, the wire 110 on the first surface F1 of the substrate 100 includes an anode input terminal wire WP, a cathode input terminal wire WN, a source wire WS, a gate wire WG, and an output terminal wire WAC. A high-voltage side waveform is formed between the anode input terminal wire WP and the output terminal wire WAC. A low-voltage side waveform is formed between the output terminal wire WAC and the cathode input terminal wire WN.

As illustrated in FIG. 2, the semiconductor chip 11 is arranged on the anode input terminal wire WP or the output terminal wire WAC. A drain (or a collector) as a first electrode is provided on a bottom surface F3 of the semiconductor chip 11. The bottom surface F3 of the semiconductor chip 11 faces the first surface F1 of the substrate 100, and the drain (or the collector) is electrically connected to the anode input terminal wire WP or the output terminal wire WAC. The semiconductor chip 11 is joined to the substrate 100 with an electrically conductive sintered material, for example, a stacked film of Ti, Ni, and Au, an Ag film, or a stacked film of Au and Ag.

A gate electrode G, a source electrode S (or an emitter electrode), and an electrode M are provided on a front surface F4 of the semiconductor chip 11 opposite the bottom surface F3.

As illustrated in FIG. 3, the common electrode plates 120g, 120s, 120p, and 120n are provided on the front surface F4 of the semiconductor chip 11. The common electrode plates 120g, 120s, 120p, and 120n connect the gate electrode G and the source electrode S of the semiconductor chip 11 and the gate wire WG, the source wire WS, and the cathode input terminal wire WN or the output terminal wire WAC to each other.

For example, as illustrated in FIG. 3, the common electrode plate 120g is connected between each of the gate electrodes G of the semiconductor chips 11 and the gate wire WG in common. The common electrode plate 120s is connected between each of the source electrodes S of the semiconductor chips 11 and the source wire WS in common. The common electrode plate 120p is connected between the electrodes M of the upper three semiconductor chips 11 in FIG. 3 and the output terminal wire WAC in common. The common electrode plate 120n is connected between the electrodes M of the lower three semiconductor chips 11 in FIG. 3 and the cathode input terminal wire WN in common. The electrodes M are respectively connected to the source electrodes S of the semiconductor chips 11. As described above, the electrodes G, S, and M on the front surface F4 of each semiconductor chip 11 are electrically connected to the wires WG, WS, WAC, and WN on the substrate 100 by the common electrode plates 120g, 120s, 120p, and 120n. In the following description, the common electrodes 120g, 120s, 120p, and 120n are also called common electrode plates 120 collectively, the wires WG, WS, WAC, and WN are also called the wires 110 collectively, and the electrodes G, S, and M are also called electrodes G and the like collectively.

The common electrode plates 120 are made of a material having electrical conductivity and thermal conductivity such as copper, aluminum, molybdenum, and tungsten. The thickness of each common electrode plate 120 is 400 to 1000 μm, for example. As illustrated in FIG. 3, each common electrode plate 120 is a plate-like connector and has any planar shape in plan view as viewed from the Z-direction. As illustrated in FIG. 4, in the cross-section, each common electrode plate 120 extends in the X-Y plane from any of the electrodes G and the like on the front surface F4 of the semiconductor chip 11 and is bent toward the wire 110 on the substrate 100 to the −Z-direction. Accordingly, each common electrode plate 120 electrically connects any of the electrodes G and the like on the front surface F4 of the semiconductor chip 11 and the corresponding one of the wires 110 on the substrate 100 to each other.

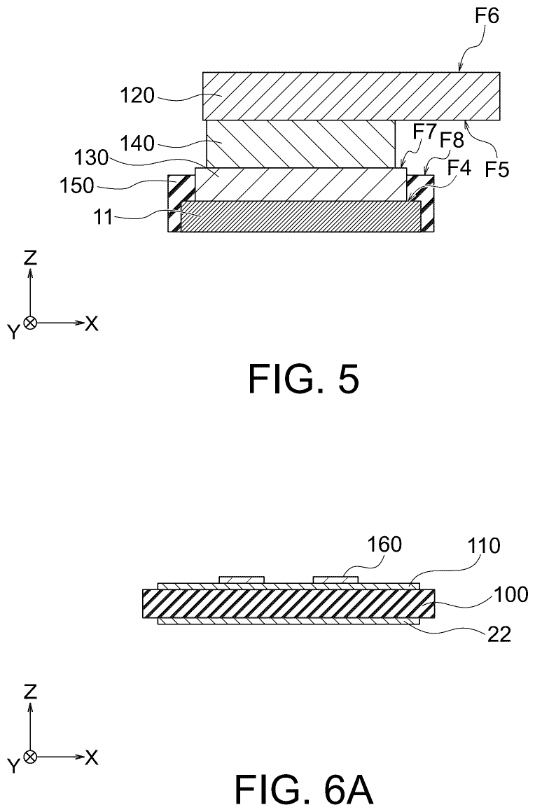

FIG. 5 is a cross-sectional view illustrating a configuration example of a connecting part between a semiconductor chip and a common electrode plate. Each common electrode plate 120 has a fifth surface F5 facing the front surface F4 of the semiconductor chip 11. One end of the common electrode plate 120 is electrically connected to any of the electrodes G and the like of the semiconductor chip 11 via a sintered material 140 and a plated metal 130 that are provided between the fifth surface F5 and the front surface F4 of the semiconductor chip 11. Although not illustrated in FIG. 5, the other end of the common electrode plate 120 is electrically connected to any of the wires 110 on the substrate 100 via a sintered material and a plated metal (both not illustrated) that are provided between the fifth surface F5 and the wires 110 on the substrate 100.

The plated metal 130 as a first plated metal is provided on the electrodes G and the like of the semiconductor chip 11. The plated metal 130 contains any of copper, nickel, silver, gold, and palladium (Pd), for example, and is specifically made of a material having high electrical conductivity and thermal conductivity, such as NiAu and Cu. The thickness of the plated metal 130 is 1 to 15 μm, for example. Other plated metals can be made of the identical material to the plated metal 130.

The sintered material 140 as a first sintered material is provided on the plated metal 130. The sintered material 140 is made of any of copper, silver, lead, a tin-copper compound, a tin-silver compound, and a tin-nickel compound. The thickness of the sintered material 140 is 10 to 300 μm, for example. The sintered material 140 is a material in the form of paste or sheet when being supplied originally, and is sintered between the plated metal 130 and the common electrode plate 120 by heat treatment. Other sintered materials can be made of the identical material to the sintered material 140.

As described above, the common electrode plates 120 are joined to the sintered material 140, thereby being electrically connected to the electrodes G and the like of the semiconductor chip 11 via the plated metal 130.

Side surfaces of the semiconductor chip 11 and side surfaces of the plated metal 130 are coated with an insulating layer 150. The insulating layer 150 is made of an insulating material such as polyimide. The thickness of the insulating layer 150 is 5 to 10 μm, for example. In the Z-direction in which the semiconductor chip 11 and the common electrode plate 120 are stacked on the substrate 100, a front surface (eighth surface) F8 of the insulating layer 150 is at a level higher than the front surface F4 of the semiconductor chip 11 and lower than a front surface (seventh surface) F7 of the plated metal 130. Accordingly, the insulating layer 150 can protect the side surfaces of the semiconductor chip 11 and the side surfaces of the plated metal 130 while maintaining the property of dissipating heat from the sintered material 140 and the common electrode plate 120.

The semiconductor device 1 according to the present embodiment includes the common electrode plates 120 that are each electrically connected to the corresponding electrodes G of the semiconductor chips 11 in common and that are electrically connected to the wires 110 on the substrate 100. Accordingly, wire bonding is no longer necessary, and the electrodes G and the like of each semiconductor chip 11 and the wires 110 on the substrate 100 can be connected by the common electrode plates 120 with low resistance. By using the common electrode plates 120, it is possible to stack the material 140 and the common electrode plates 120 on the semiconductor chip 11 and to pressurize and sinter the material 140 and the common electrode plate 120. Accordingly, the common electrode plates 120 can connect the electrodes G and the like of each semiconductor chip 11 and the wires 110 on the substrate 100 to each other with low resistance and can provide the high heat-dissipation property to the semiconductor device 1. It is also possible to make the semiconductor device 1 have a substantially uniform thickness.

Furthermore, use of the common electrode plates 120 in place of wire bonding enables the electrodes G and the like of the semiconductor chips 11 to be connected to the wires 110 in common at the same time. Therefore, the number of parts constituting the semiconductor device 1 can be reduced.

Next, a manufacturing method of the semiconductor device 1 according to the present embodiment is described.

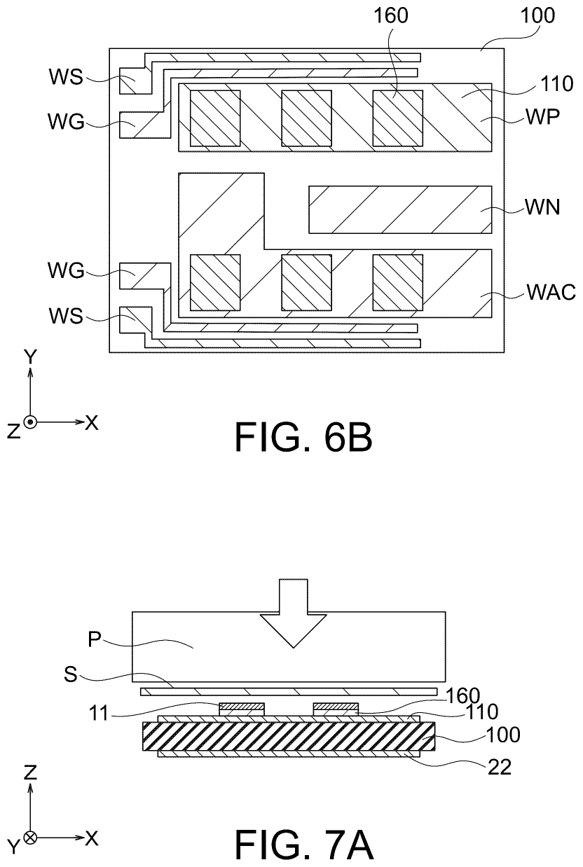

FIGS. 6A to 11 are cross-sectional views and plan views illustrating an example of the manufacturing method of the semiconductor device according to the first embodiment.

As illustrated in FIGS. 6A and 6B, a material to be sintered 160 is applied on the wire 110 on the substrate 100. The material 160 is applied at a position at which the semiconductor chip 11 is to be arranged. The material 160 is made of any of copper, silver, lead, a tin-copper compound, a tin-silver compound, and a tin-nickel compound.

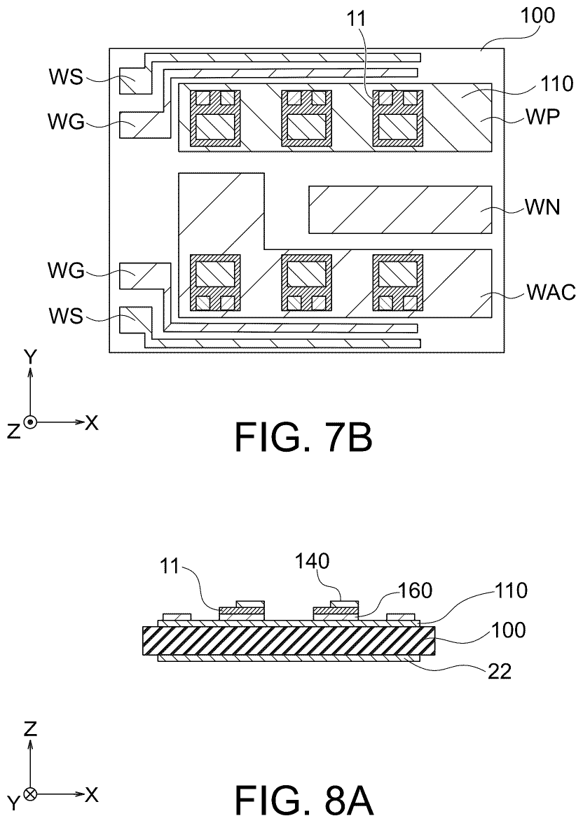

Next, as illustrated in FIGS. 7A and 7B, the semiconductor chip 11 is placed on the material 160. The semiconductor chip 11 is arranged at the position of the material 160 applied on the wire 110 on the substrate 100.

As illustrated in FIG. 7A, the semiconductor chip 11 is then pressurized from the Z-direction by means of a pressurizer P. In this process, a shock absorber S is sandwiched between the pressurizer P and the semiconductor chip 11 to prevent the pressurizer P from damaging the semiconductor chip 11. While the pressurizer P pressurizes the semiconductor chip 11, the material 160 is heated to be sintered. Accordingly, the semiconductor chip 11 is joined to the wire 110 with the sintered material 160, thereby being electrically connected to the wire 110 with low resistance.

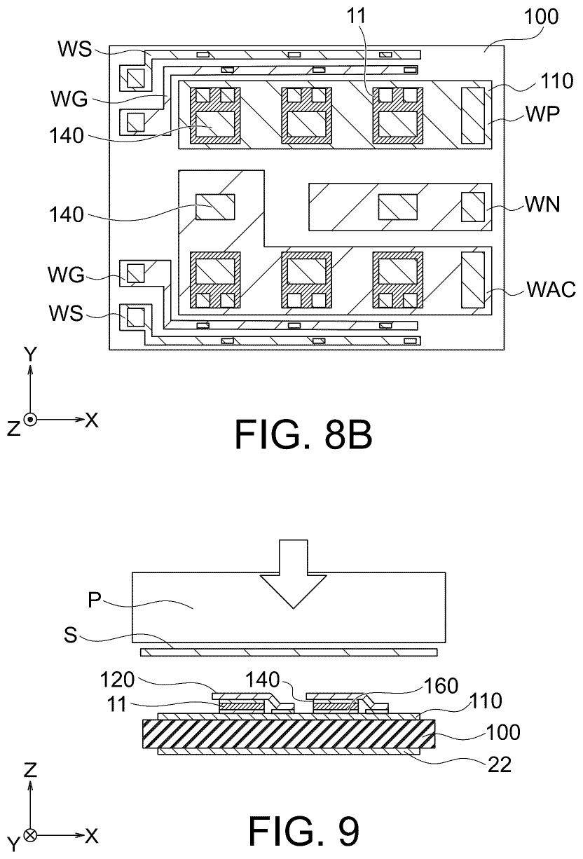

Next, as illustrated in FIGS. 8A and 8B, the material to be sintered 140 is applied on the electrodes G and the like of the semiconductor chip 11 and on the wire 110 on the substrate 100. The material 140 is applied at a position at which the common electrode plate 120 is to be arranged. The material 140 is made of any of copper, silver, lead, a tin-copper compound, a tin-silver compound, and a tin-nickel compound.

Next, as illustrated in FIGS. 9 and 3, the common electrode plates 120 are placed on the material 140. The common electrode plates 120 are arranged at the positions of the material 140 applied on the electrodes G and the like of the semiconductor chip 11 and on the wires 110 on the substrate 100. For example, as illustrated in FIG. 3, the common electrode plate 120g is arranged on the material 140 applied on the electrode G of the semiconductor chip 11 and on the wire WG on the substrate 100. The common electrode plate 120s is arranged on the material 140 applied on the electrode S of the semiconductor chip 11 and on the wire WS on the substrate 100. The common electrode plate 120p is arranged on the material 140 applied on the electrodes M of the upper three semiconductor chips 11 in FIG. 3 and on the wire WAC on the substrate 100. The common electrode plate 120n is arranged on the material 140 applied on the electrodes M of the lower three semiconductor chips 11 in FIG. 3 and on the wire WN on the substrate 100.

As illustrated in FIG. 9, the common electrode plates 120 are then pressurized from the Z-direction by means of the pressurizer P. In this process, the shock absorber S is sandwiched between the pressurizer P and the semiconductor chips 11 to prevent the pressurizer P from damaging the common electrode plates 120 and the semiconductor chips 11. While the pressurizer P pressurizes the common electrode plates 120, the material 140 is heated to be sintered. Accordingly, the common electrode plates 120 are joined to the electrodes G and the like of the semiconductor chips 11 and the wires 110 on the substrate 100 with the sintered material 140, thereby being electrically connected to the electrodes G and the like of the semiconductor chips 11 and the wires 110 on the substrate 100 with low resistance. With this configuration, the semiconductor module 10 is formed.

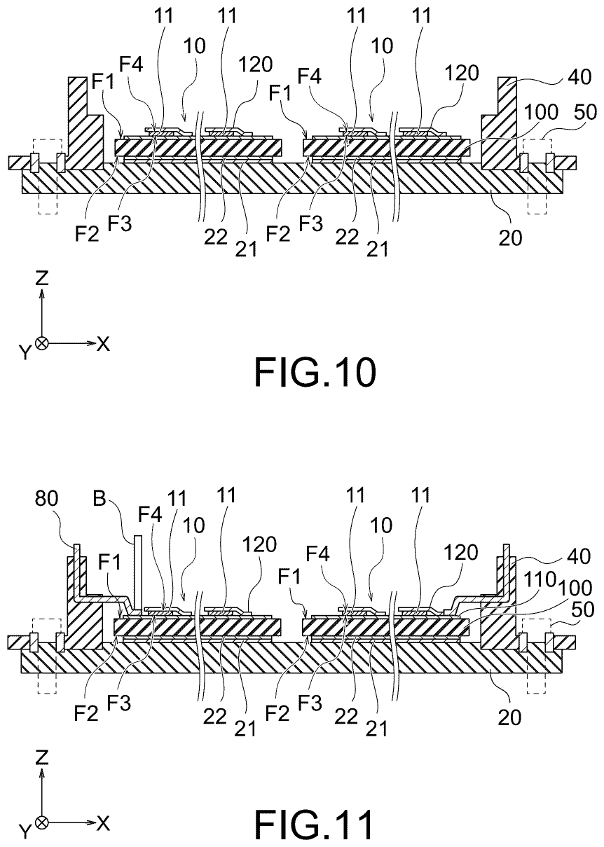

Next, as illustrated in FIG. 10, the semiconductor modules 10 are joined onto the base 20 with the solder 21. The base 20 is made of a material having high thermal conductivity, such as AlSiC obtained by coating an SiC substrate with aluminum. Therefore, heat generated in the semiconductor modules 10 can be transferred to the base 20 via the wire 22 and the solder 21 and be transferred from the base 20 to the heat-dissipation fin 90 in FIG. 1 easily.

Next, the housing 40 is arranged to surround the semiconductor modules 10 on the base 20. The housing 40 is fixed to the base 20 with the fastener 50. At this time, the heat-dissipation fin 90 illustrated in FIG. 1 may also be fixed to the base 20 with the fastener 50 along with the housing 40.

Next, as illustrated in FIG. 11, the wire 80 is ultrasonic-joined to the wire 110 on the substrate 100 by means of an ultrasonic joining tool B. The wire 80 penetrates through the housing 40 and is led out to outside thereof. Accordingly, a user can supply a signal from outside or power to each semiconductor module 10 via the wire 80.

Thereafter, the gel-like encapsulation material 60 is put on the semiconductor modules 10 in the housing 40, and the cover 70 is fitted to the housing 40. In this way, the semiconductor device 1 illustrated in FIG. 1 is completed.

According to the present embodiment, it is possible to stack the material to be sintered 140 and the common electrode plates 120 on the semiconductor chip 11 and to pressurize and sinter the material 140 and the common electrode plates 120. Accordingly, the common electrode plates 120 can connect the electrodes G and the like of each semiconductor chip 11 and the wires 110 on the substrate 100 to each other with low resistance and can provide the high heat-dissipation property to the semiconductor device 1. It is also possible to make the semiconductor device 1 have a substantially uniform thickness.

Furthermore, use of the common electrode plates 120 in place of wire bonding enables the electrodes G and the like of the semiconductor chips 11 to be connected to the wires 110 at the same time. Therefore, the number of parts constituting the semiconductor device 1 can be reduced.

### Second Embodiment

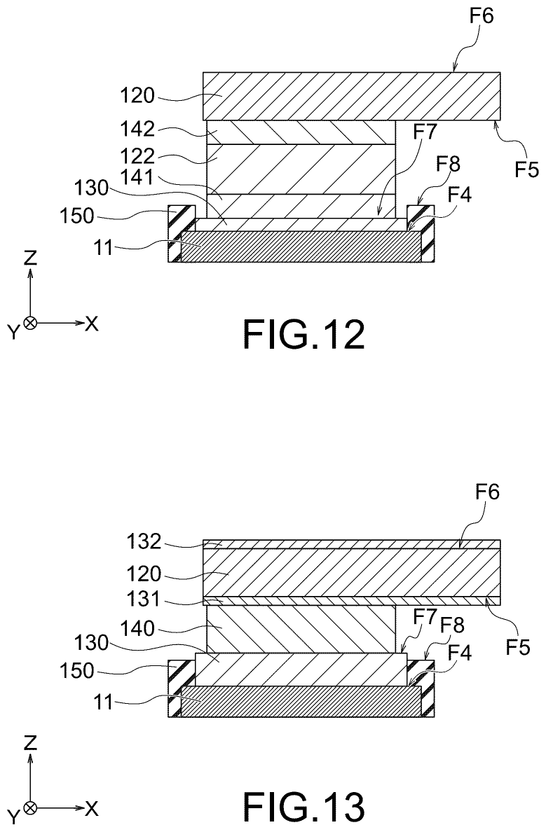

FIG. 12 is a cross-sectional view illustrating a configuration example of a connecting part between a semiconductor chip and a common electrode plate according to a second embodiment. In the second embodiment, an intermediate electrode plate 122 is provided between the semiconductor chip 11 and the common electrode plate 120. Sintered materials 141 and 142 are provided on both surfaces in the Z-direction of the intermediate electrode plate 122. The sintered material 141 as a second sintered material is provided on the plated metal 130. The sintered material 142 as a third sintered material is provided between the intermediate electrode plate 122 and the common electrode plate 120. The sintered materials 141 and 142 are made of any of copper, silver, lead, a tin-copper compound, a tin-silver compound, and a tin-nickel compound. The thickness of each of the sintered materials 141 and 142 is 10 to 100 μm.

The intermediate electrode plate 122 may be made of the same material as the common electrode plate 120. In plan view as viewed from the Z-direction, the intermediate electrode plate 122 is formed to have such a size that it can be accommodated within each of the electrodes G and the like of the semiconductor chip 11. The thickness of the intermediate electrode plate 122 is 100 to 300 μm.

The front surface F8 of the insulating layer 150 may be at a level higher than the front surface F7 of the plated metal 130 provided on the electrodes G and the like of the semiconductor chip 11 in the Z-direction. Since the intermediate electrode plate 122 is interposed between the common electrode plate 120 and the semiconductor chip 11, the front surface F7 of the plated metal 130 may be lower than the front surface F8 of the insulating layer 150.

A manufacturing method of the semiconductor device 1 according to the second embodiment is described.

After the processes described with reference to FIGS. 6A to 7B, in place of the material to be sintered 140 in FIGS. 8A and 8B, the material to be sintered 141 in FIG. 12 is applied on the electrodes G and the like of the semiconductor chip 11 and on the wires 110 on the substrate 100, the intermediate electrode plate 122 is placed on the material 141, and the material to be sintered 142 is applied on the intermediate electrode plate 122.

Next, after the processes described with reference to FIGS. 9 and 3, the common electrode plate 120 is placed at the position of the material 142. The common electrode plate 120 is pressurized from the Z-direction by means of the pressurizer P, and the material 141 and 142 is sintered. Accordingly, the intermediate electrode plate 122 is joined to the electrodes G and the like of the semiconductor chip 11 with the material 141, and the common electrode plate 120 is joined to the intermediate electrode plate 122 and the wires 110 on the substrate 100 with the material 142. With this configuration, the semiconductor module 10 according to the second embodiment is formed. The rest of the configuration and the manufacturing process of the second embodiment may be identical to those of the first embodiment. Accordingly, the second embodiment can obtain effects same as those of the first embodiment.

### Third Embodiment

FIG. 13 is a cross-sectional view illustrating a configuration example of a connecting part between a semiconductor chip and a common electrode plate according to a third embodiment. The third embodiment further includes plated metals 131 and 132. The plated metal 131 is provided on the fifth surface F5 of the common electrode plate 120. The plated metal 132 is provided on a sixth surface F6 of the common electrode plate 120 opposite the fifth surface F5. The plated metals 131 and 132 contain any of copper, nickel, silver, gold, and palladium (Pd), for example, and are specifically made of a material having high electrical conductivity and thermal conductivity such as NiAu and Cu. By providing the plated metals 131 and 132 on both the front and back surfaces of the common electrode plate 120, surface oxidation of the common electrode plate 120 (e.g., copper) is prevented. Accordingly, the common electrode plate 120 can be joined to the sintered material 140 more firmly.

The rest of the configuration and the manufacturing process of the third embodiment may be identical to those of the first embodiment. Accordingly, the third embodiment can obtain effects same as those of the first embodiment.

### Fourth Embodiment

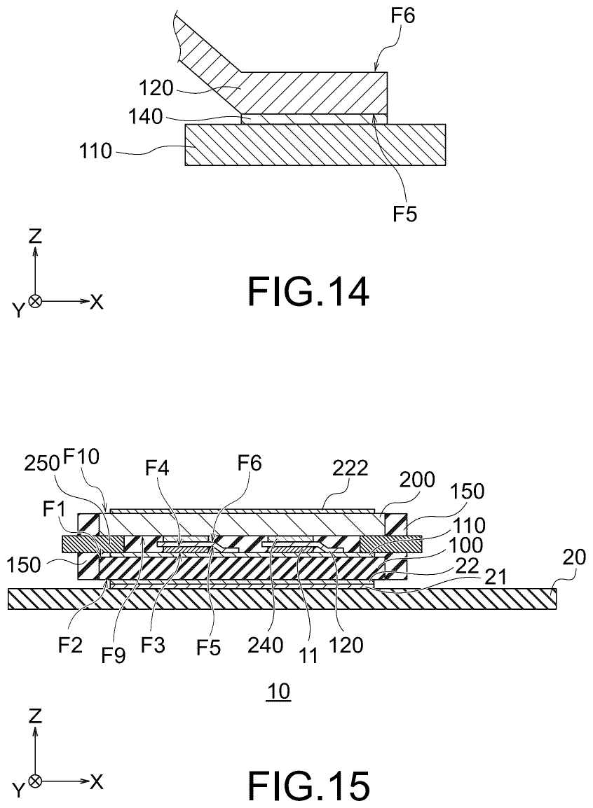

FIG. 14 is a cross-sectional view illustrating a configuration example of a connecting part between a common electrode plate and a wire on a substrate according to a fourth embodiment. The common electrode plate 120 is joined to the wire 110 on the substrate 100 with the sintered material 140. Instead of the sintered material 140, a plated metal (not illustrated) may be used. The plated metal contains any of copper, nickel, silver, gold, and palladium (Pd), for example, and is specifically made of a material having high electrical conductivity and thermal conductivity such as NiAu and Cu. The common electrode plate 120 can be joined to the wire 110 with the sintered material 140 or the plated metal firmly. The plated metal may be formed by a wet process, vapor deposition, ion plating, sputtering, or the like.

The rest of the configuration and the manufacturing process of the fourth embodiment may be identical to those of the first embodiment. Accordingly, the fourth embodiment can obtain effects same as those of the first embodiment.

### Fifth Embodiment

FIG. 15 is a cross-sectional view illustrating a configuration example of a semiconductor module according to a fifth embodiment. The semiconductor module 10 according to the fifth embodiment includes the substrate 100 provided on the bottom surface F3 side of the semiconductor chip 11 (the fifth surface F5 side of the common electrode plate 120) and a substrate 200 provided on the front surface F4 side of the semiconductor chip 11 (the sixth surface F6 side of the common electrode plate 120). That is, the substrates 100 and 200 are provided on both the bottom surface F3 side and the front surface F4 side of the semiconductor chip 11. Similarly to the substrate 100, the substrate 200 is also made of an insulating material having high thermal conductivity, such as ceramic.

A terminal 250 is provided between the substrate 100 and the substrate 200. The terminal 250 is electrically connected to a portion of the wire 110 when pressurized by the pressurizer P, and functions as a terminal led out to outside of the semiconductor module 10. For example, the terminal 250 may be electrically connected to the wire 80 in FIG. 1 and be led out to outside of the housing 40. The terminal 250 also functions as a spacer between the substrate 100 and the substrate 200 when pressurized by the pressurizer P. Therefore, the terminal 250 maintains the gap between the substrate 100 and the substrate 200 so as to prevent the substrates 100 and 200 from being bent and damaged.

The substrate 200 is joined to the common electrode plate 120 with a sintered material 240 provided on the sixth surface F6 of the common electrode plate 120. The sintered material 240 contains any of copper, nickel, silver, gold, and palladium (Pd), for example, and is specifically made of a material having high electrical conductivity and thermal conductivity such as NiAu and Cu.

A nineth surface F9 of the substrate 200 faces the sixth surface F6 of the common electrode plate 120 and the front surface F1 of the substrate 100. A tenth surface F10 of the substrate 200 is an opposite surface to the nineth surface F9. A wire 222 is provided on the tenth surface F10 of the substrate 200. The wire 222 is made of a material that has high electrical conductivity and thermal conductivity, such as copper. Accordingly, heat of the semiconductor chip 11 is dissipated not only via the substrate 100 but also via the substrate 200. That is, the semiconductor chip 11 is a so-called DSC (Double Side Cooling) semiconductor device that dissipates heat from both the bottom surface F3 and the front surface F4 of the semiconductor chip 11.

The semiconductor device 1 according to the fifth embodiment can improve the heat-dissipation property of the semiconductor chip 11. The rest of the configuration of the fifth embodiment may be identical to that of the first embodiment. Accordingly, the fifth embodiment can obtain effects same as those of the first embodiment. The fifth embodiment may be combined with any of the second to fourth embodiments. With this combination, the fifth embodiment can obtain any of effects of the second to fourth embodiments.

A manufacturing method of the semiconductor device 1 according to the fifth embodiment is described.

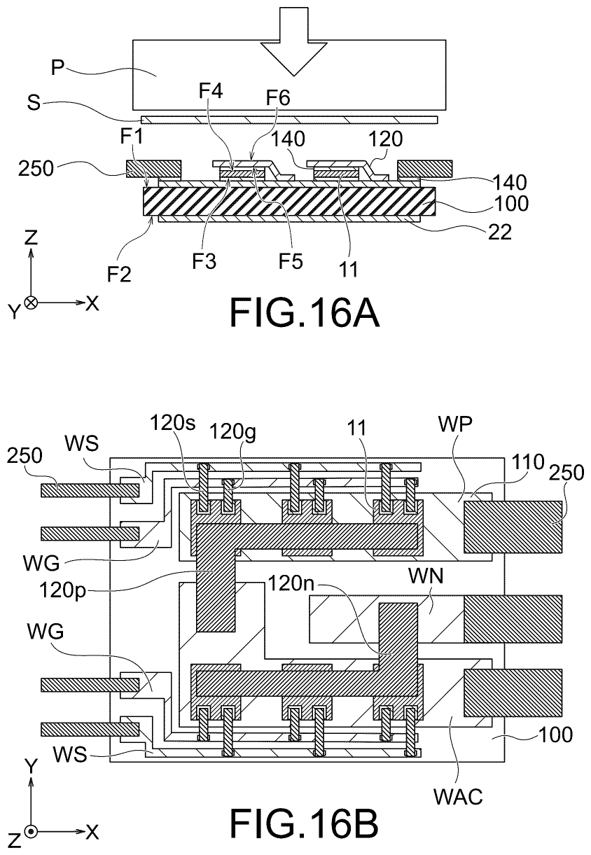

FIGS. 16A to 18B are cross-sectional views and plan views illustrating an example of the manufacturing method of the semiconductor device according to the fifth embodiment.

After the processes described with reference to FIGS. 6A to 8B, the material to be sintered 140 is applied on the semiconductor chip 11 and the wire 110.

Next, as illustrated in FIGS. 16A and 16B, the common electrode plate 120 is arranged on the material to be sintered 140 on the semiconductor chip 11, and the terminal 250 is arranged on the material to be sintered 140 on the wire 110. As illustrated in FIG. 16B, the terminals 250 are arranged on the wires WG, WS, WP, WN, and WAC and led out to outside of the substrate 100.

As illustrated in FIG. 16A, the common electrode plate 120 and the terminal 250 are then pressurized from the Z-direction by means of the pressurizer P. In this process, the shock absorber S is sandwiched between the pressurizer P and the semiconductor chip 11 to prevent the pressurizer P from damaging the common electrode plates 120 and the semiconductor chip 11. The terminal 250 functions as a spacer, thereby preventing local application of excessive pressure to the common electrode plate 120, the semiconductor chip 11, and the substrate 100. While the pressurizer P pressurizes the common electrode plate 120 and the terminal 250, the material to be sintered 140 is heated to be sintered. Accordingly, the common electrode plates 120 are joined to the electrodes G and the like of the semiconductor chip 11 and the wires 110 on the substrate 100 with the sintered material 140, thereby being electrically connected to the electrodes G and the like of the semiconductor chip 11 and the wires 110 on the substrate 100 with low resistance. The terminal 250 is joined to the wire 110 with the sintered material 140, so that the wire 110 on the substrate 100 can be led out to outside of the semiconductor device 1.

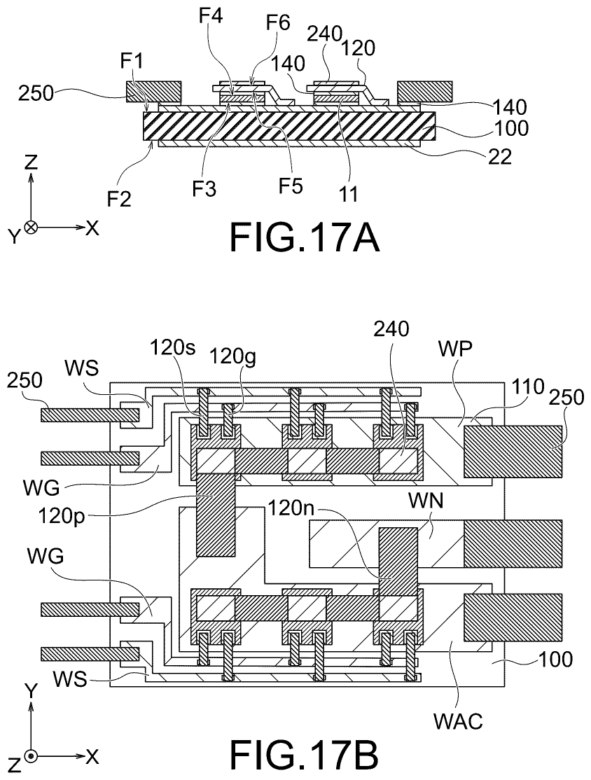

Next, as illustrated in FIGS. 17A and 17B, the material to be sintered 240 is applied on the common electrode plate 120.

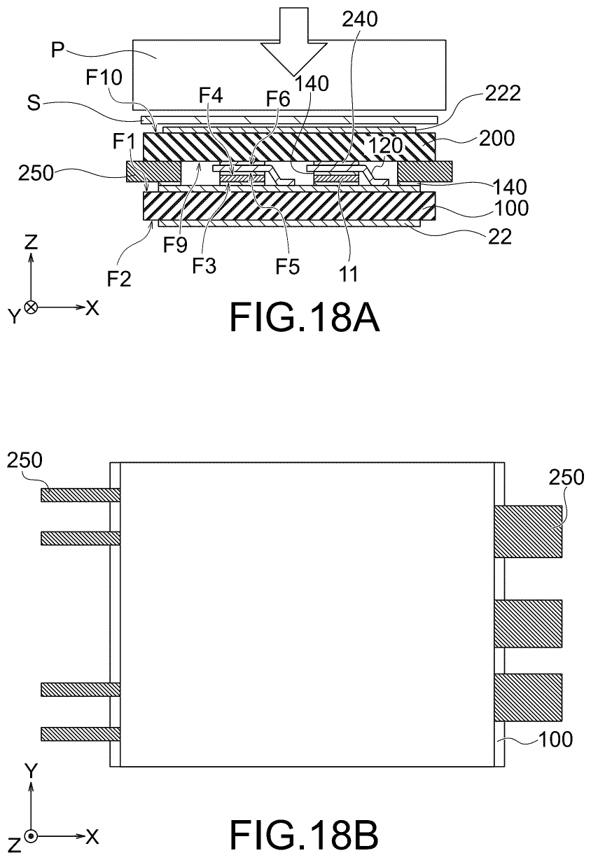

Next, as illustrated in FIGS. 18A and 18B, the substrate 200 is arranged on the material 240 on the common electrode plate 120. The nineth surface F9 of the substrate 200 faces the common electrode plate 120 via the material 240. The substrate 200 is also provided on the terminal 250 to sandwich the terminal 250 between the substrate 200 and the substrate 100.

Next, the wire 222 is formed on the tenth surface F10 of the substrate 200 located on the opposite side of the nineth surface F9.

As illustrated in FIG. 18A, the substrate 200 is then pressurized from the Z-direction by means of the pressurizer P. In this process, the shock absorber S is sandwiched between the pressurizer P and the semiconductor chip 11 to prevent the pressurizer P from damaging the substrate 200 and the like. The terminal 250 functions as a spacer, thereby preventing local application of excessive pressure to the substrate 200. While the pressurizer P pressurizes the substrate 200, the material 240 is heated to be sintered. Accordingly, the substrate 200 is joined to the common electrode plate 120 with the sintered material 240. Although the terminal 250 is sandwiched between the substrate 100 and the substrate 200 and led to outside of the semiconductor device 1, the terminal 250 can be connected to the wire 110 securely.

Next, as illustrated in FIG. 15, the surroundings of the substrates 100 and 200 and the semiconductor chip 11 are encapsulated by the insulating layer 150. At this time, a portion of the terminal 250 protrudes from the insulating layer 150. Accordingly, electrical connection from outside of the semiconductor device 1 to the semiconductor chip 11 can be achieved. The wires 22 and 222 are exposed from the insulating layer 150. This configuration enables easy heat dissipation from the substrates 100 and 200.

The rest of the manufacturing process of the fifth embodiment may be identical to that of the first embodiment. Accordingly, the fifth embodiment can obtain effects same as those of the first embodiment.

### Sixth Embodiment

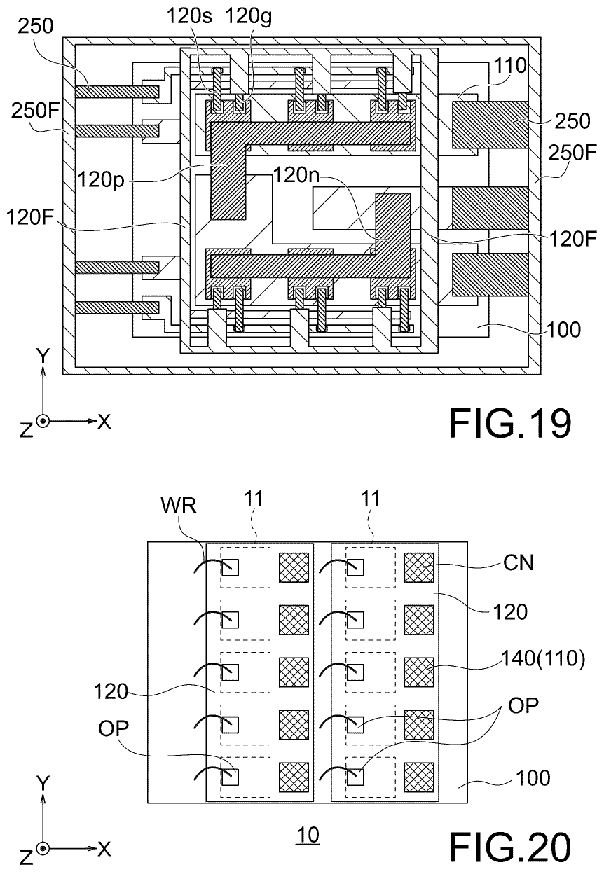

FIG. 19 is a cross-sectional view illustrating an example of a manufacturing method of the semiconductor device 1 according to a sixth embodiment. The configuration of the sixth embodiment may be identical to that of the fifth embodiment.

The manufacturing method according to the sixth embodiment is described.

After the processes described with reference to FIGS. 6A to 8B, the material to be sintered 140 is applied on the semiconductor chip 11 and the wire 110.

Next, as illustrated in FIG. 19, some of the common electrode plates 120 are arranged while being connected to each other by a frame 120F. The terminals 250 are arranged while being connected to each other by a frame 250F. The frame 120F couples the common electrode plates 120 to each other, and the frame 250F couples the terminals 250 to each other.

Subsequently, as described with reference to FIG. 16A, the common electrode plates 120, the frame 120F, the terminals 250, and the frame 250F are pressurized from the Z-direction by means of the pressurizer P. While the pressurizer P pressurizes the common electrode plates 120, the frame 120F, the terminals 250, and the frame 250F, the material 140 is heated to be sintered. Accordingly, the common electrode plates 120 are joined to the electrodes of the semiconductor chip 11 and the wires 110 with the sintered material 140 along with the frame 120F. The terminals 250 are joined to the wires 110 with the sintered material 140 along with the frame 250F.

Thereafter, the frames 120F and 250F are cut out, and the common electrode plates 120 and the terminals 250 are left on the semiconductor chip 11 and the wires 110. Accordingly, the same configuration as that in FIG. 16B can be obtained.

The rest of the manufacturing process of the sixth embodiment may be identical to that of the fifth embodiment. Accordingly, the sixth embodiment can obtain effects same as those of the fifth embodiment. The frame 120F couples the common electrode plates 120 to each other, and the frame 250F couples the terminals 250 to each other. Therefore, the number of parts to be handled in a manufacturing process of the semiconductor device 1 can be reduced.

In the sixth embodiment, the substrate 200 and the wire 222 may be provided, as in the fifth embodiment. However, the substrate 200 and the wire 222 may be omitted in the sixth embodiment.

### Seventh Embodiment

FIG. 20 is a plan view illustrating a configuration example of a semiconductor module according to a seventh embodiment. The common electrode plate 120 according to the seventh embodiment has an opening OP through which the gate electrode G is exposed. The semiconductor chip 11 has the gate electrode G on its front surface, and the opening OP is formed in a region of the gate electrode G. With this configuration, the gate electrode G is electrically isolated from the common electrode plate 120 and can be electrically connected to the wire WG or the like (see FIG. 17B) with a metal wire WR or another metal plate. A connector CN is a connecting portion between the common electrode plate 120 and the wire 110 and is a portion at which the sintered material 140 is provided.

Use of the metal wire WR in connection to the gate electrode G increases the wiring flexibility. Meanwhile, the common electrode plate 120 is used in connection to other electrodes and wires. The rest of the configuration of the seventh embodiment may be identical to that of the first embodiment. Accordingly, the seventh embodiment can also obtain the effects of the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first insulating substrate having a first surface and a second surface opposite the first surface;
first and second electrically conductive layers provided on a side of the first surface;
a plurality of semiconductor chips each having a third surface facing the first surface, a fourth surface opposite the third surface, a first electrode provided on the third surface, and a second electrode provided on the fourth surface, the first electrode being electrically connected to the first electrically conductive layer;
a common electrode plate having a fifth surface that faces the fourth surface, electrically connected to the second electrodes of the semiconductor chips in common, and electrically connected to the second electrically conductive layer; and
a second insulating substrate provided on a side of the second surface of the first insulating substrate.

2. The device of claim 1, further comprising:
a first plated metal provided on the second electrodes of the semiconductor chips; and
a first sintered material provided on the first plated metal, wherein the common electrode plate is electrically connected to the second electrodes of the semiconductor chips by being joined to the first sintered material.

3. The device of claim 1, further comprising a joining material provided between the first insulating substrate and the second insulating substrate.

4. The device of claim 2, further comprising an insulating layer provided on side surfaces of the semiconductor chips and side surfaces of the first plated metal, wherein a height of the insulating layer in a first direction in which the semiconductor chip and the common electrode plate are stacked on the first insulating substrate is higher than the semiconductor chip and lower than the first plated metal.

5. The device of claim 1, further comprising:
a plurality of intermediate electrode plates provided between the respective semiconductor chips and the common electrode plate;
a first plated metal provided on the second electrodes of the semiconductor chips;
a second sintered material provided on the first plated metal; and
a third sintered material provided between the intermediate electrode plates and the common electrode plate.

6. The device of claim 5, further comprising an insulating layer provided on side surfaces of the semiconductor chips and side surfaces of the first plated metal, a height of the insulating layer in a first direction in which the semiconductor chip and the common electrode plate are stacked on the first insulating substrate being higher than the first plated metal.

7. The device of claim 2, further comprising:
a second plated metal provided on the fifth surface of the common electrode plate; and
a third plated metal provided on a sixth surface of the common electrode plate opposite the fifth surface.

8. The device of claim 1, wherein the common electrode plate and the second electrically conductive layer are joined to each other with solder.

9. The device of claim 1, further comprising a third insulating substrate provided above a sixth surface of the common electrode plate opposite the fifth surface.

10. The device of claim 9, further comprising an electrically conductive terminal sandwiched between the second insulating substrate and the third insulating substrate and electrically connected to the first electrically conductive layer or the second electrically conductive layer.

11. The device of claim 10, further comprising a fourth sintered material provided between the common electrode plate and the third insulating substrate.

12. The device of claim 7, wherein the first to third plated metals contain any of copper, nickel, silver, gold, and palladium.

13. The device of claim 2, wherein the first sintered material contains any of copper, silver, lead, a tin-copper compound, a tin-silver compound, and a tin-nickel compound.

14. The device of claim 1, wherein the common electrode plate has openings in regions of third electrodes provided on the fourth surfaces of the semiconductor chips, respectively, and is electrically isolated from the third electrodes.

15. The device of claim 1, further comprising:
a housing fixed to the second insulating substrate and accommodating the first insulating substrate, the semiconductor chips, and the common electrode plate in a space surrounded by the second insulating substrate and the housing; and
a gel encapsulating the first insulating substrate, the semiconductor chips, and the common electrode plate in the space.

16. The device of claim 1, further comprising mold resin encapsulating the first insulating substrate, the semiconductor chips, and the common electrode plate on the second insulating substrate.

17. The device of claim 1, wherein the semiconductor chips each include a high-voltage power semiconductor element with a breakdown voltage of 800 V or more.

18. The device of claim 1, wherein the semiconductor chips each include an IGBT (Insulated Gate Bipolar Transistor), an HEMT (High Electron Mobility Transistor), a MOSFET (Metal Oxide Semiconductor Field Effect Transistor), or a diode using an SiC substrate.
